(19) United States
(12) Patent Application Publication
(10) Pub. No.: US 2024/0080025 A1
(43) Pub. Date: Mar. 7, 2024

(54) PIEZOELECTRIC UNIT AND INPUT-OUTPUT DEVICE

(71) Applicant: OMRON Corporation, KYOTO (JP)

(72) Inventors: Shogo NAGASAKA, Kyoto-shi (JP); Yoshinori SHIMIZU, Kyoto-shi (JP)

(73) Assignee: OMRON Corporation, KYOTO (JP)

(21) Appl. No.: 18/448,987

(22) Filed: Aug. 14, 2023

(30) Foreign Application Priority Data
Sep. 5, 2022 (JP) 2022-140445

(51) Int. Cl. H03K 17/96; G06F 3/01; G06F 3/0354

(52) U.S. Cl. CPC H03K 17/964; G06F 3/016; G06F 3/03547; H03K 2217/96062

(57) ABSTRACT

A piezoelectric unit includes a piezoelectric element, an output part, an input part, and a control part. The output part performs an output vibrating the piezoelectric element. The input part receives an input of a voltage generated by the piezoelectric element. The control part performs switching such that the output performed by the output part and the input performed by the input part alternate with each other. An input-output device includes a housing that accommodates the piezoelectric unit, and a contact part arranged on an outer surface of the housing. The contact part outputs vibration caused by the piezoelectric element and transmits an input resulting from contact from outside to the piezoelectric element.

### CROSS-REFERENCE TO RELATED APPLICATION

This application claims the priority benefit of Japan application serial no. 2022-140445, filed on Sep. 5, 2022. The entirety of the above-mentioned patent application is hereby incorporated by reference herein and made a part of this specification.

### BACKGROUND

### Technical Field

The disclosure relates to a piezoelectric unit including a piezoelectric element and an input-output device including such a piezoelectric unit.

### Related Art

Electronic devices such as smartphones and tablet computers function as input-output devices that detect an input resulting from contact of a user's finger and perform an output transmitting vibration to the user's finger. As such an input-output device, for example, Patent Document 1 (Japanese Patent Application Laid-Open No. 2005-339298) proposes an electronic device including a capacitive sensor that detects contact of a finger and an actuator that vibrates using a piezoelectric material.

However, the electronic device disclosed in Patent Document 1 is prone to an increase in size because multiple elements including the capacitive sensor and the piezoelectric material are used.

### SUMMARY

According to an embodiment, a piezoelectric unit disclosed in this application includes a piezoelectric element, an output part, an input part, and a control part. The output part performs an output vibrating the piezoelectric element. The input part receives an input of a voltage generated by the piezoelectric element. The control part performs switching such that the output performed by the output part and the input performed by the input part alternate with each other. According to an embodiment, the piezoelectric unit further includes an oscillation circuit that oscillates a periodic signal. The output performed by the output part and the input performed by the input part are switched based on the periodic signal oscillated by the oscillation circuit.

According to an embodiment, in the piezoelectric unit, the output part includes a first oscillation circuit, a second oscillation circuit, and an addition circuit. The first oscillation circuit oscillates a first signal of a first frequency. The second oscillation circuit oscillates a second signal of a second frequency different from the first frequency. The addition circuit combines a waveform of the first signal oscillated by the first oscillation circuit and a waveform of the second signal oscillated by the second oscillation circuit. The output vibrating the piezoelectric element is an output that vibrates the piezoelectric element based on a waveform combined by the addition circuit.

According to an embodiment, in the piezoelectric unit, a difference between the first frequency and the second frequency is 1 to 50 Hz.

According to an embodiment, in the piezoelectric unit, the first frequency and the second frequency are 50 to 500 Hz.

Further, according to an embodiment, an input-output device disclosed in this application includes the piezoelectric unit above, a housing that accommodates the piezoelectric unit, and a contact part arranged on an outer surface of the housing. The contact part outputs vibration caused by the piezoelectric element and transmits an input resulting from contact from outside to the piezoelectric element.

According to an embodiment, by alternately performing application of a voltage and measurement of a voltage with respect to the piezoelectric element, the piezoelectric unit disclosed in this application is capable of reducing the quantity of elements.

### BRIEF DESCRIPTION OF THE DRAWINGS

FIG. 1 is a schematic external view showing an example of the appearance of an input-output device disclosed in this application.

FIG. 2 is a schematic external view showing an example of the appearance of the input-output device disclosed in this application.

FIG. 3 is a schematic perspective view showing an example of the inside of the input-output device disclosed in this application.

FIG. 4 is a schematic external view showing an example of a piezoelectric device included in the input-output device disclosed in this application.

FIG. 5 is a circuit block diagram schematically showing an example of the functional configuration of a control device included in the piezoelectric unit disclosed in this application.

FIG. 6 is a graph showing an example of the influence of frequency on human skin sensation.

FIG. 7 is a time chart showing an example of signal waveforms related to an output part of the control device included in the piezoelectric unit disclosed in this application.

FIG. 8 is a circuit block diagram schematically showing an example of the functional configuration of the control device included in the piezoelectric unit disclosed in this application.

FIG. 9 is a time chart showing an example of general forms of signal waveforms related to a first control method of the control device included in the piezoelectric unit disclosed in this application.

FIG. 10 is a time chart showing an example of general forms of signal waveforms related to a second control method of the control device included in the piezoelectric unit disclosed in this application.

### DESCRIPTION OF THE EMBODIMENTS

Embodiments of the disclosure provide a piezoelectric unit capable of reducing a quantity of elements, and thus, for example, capable of being miniaturized.

Other embodiments of the disclosure provide an input-output device including the piezoelectric unit according to the disclosure.

### Application Examples

Hereinafter, embodiments will be described with reference to the drawings. An input-output device disclosed in this application is applied to devices that detect contact of a user's finger and transmit vibration to the contacted finger, such as game devices, controllers for game devices, smartphones, and tablet computers. Hereinafter, an input-output device IO applied to a game device will be illustrated and described with reference to the drawings.

<Appearance of Input-Output Device IO>

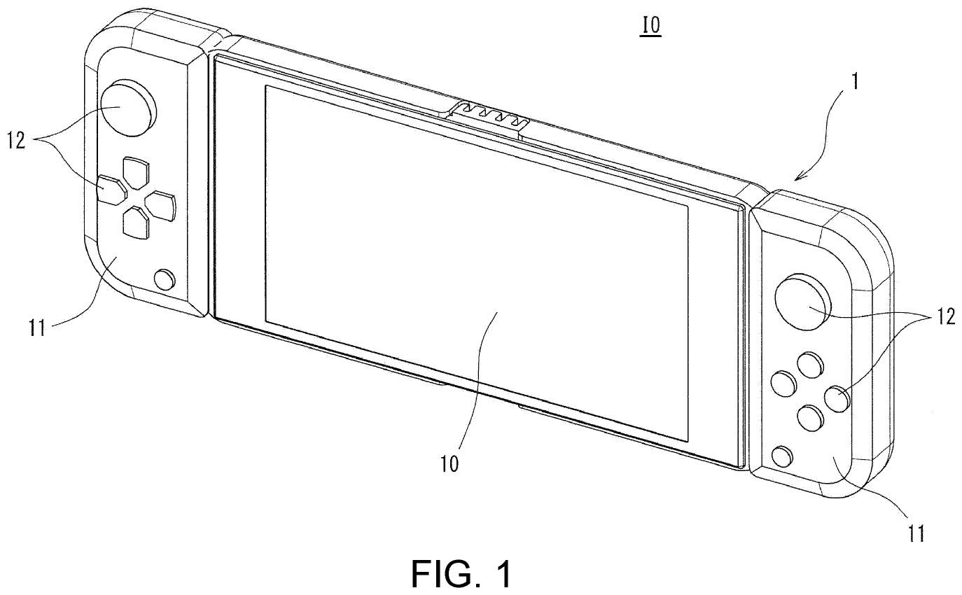

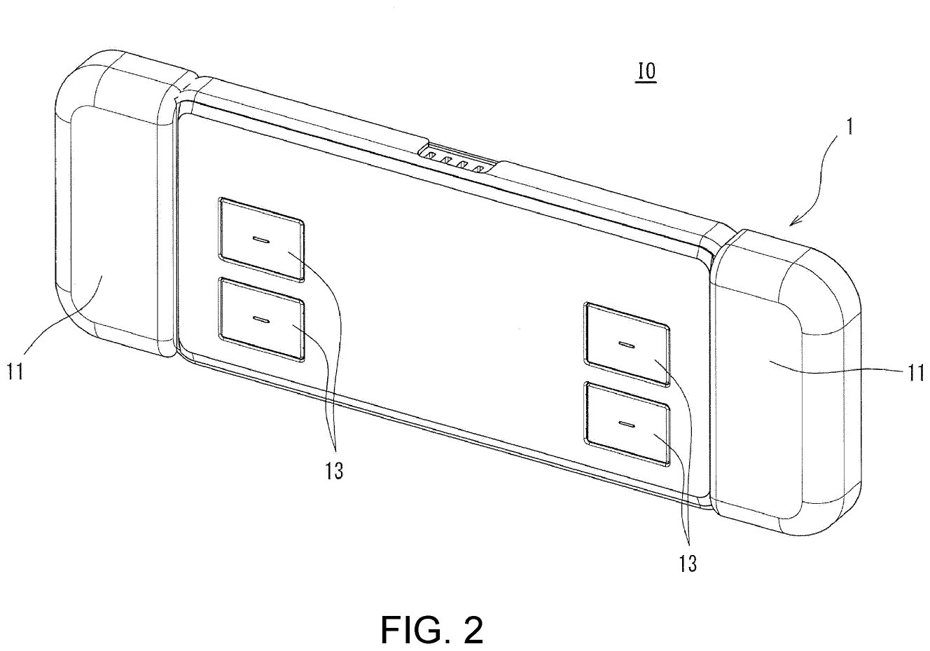

FIG. 1 and FIG. 2 are schematic external views showing an example of the appearance of the input-output device IO disclosed in this application. FIG. 1 is a schematic perspective view showing the front surface side of the input-output device IO at a center, and FIG. 2 is a schematic perspective view showing the back surface side of the input-output device IO at a center. The input-output device IO includes a housing 1 that forms a substantially rectangular plate shape. A display part 10, such as a rectangular liquid crystal panel, is arranged at the center of the front surface of the housing 1. Grip parts 11 to be gripped by the user are arranged on left and right sides of the display part 10. Operation parts 12 such as operation buttons to be operated by the user with his or her thumbs are arranged at the grip parts 11. On the back surface (outer surface) of the housing 1, contact parts 13 are arranged at four positions touched by fingers other than the thumbs of the user.

<Internal Structure of Input-Output Device IO>

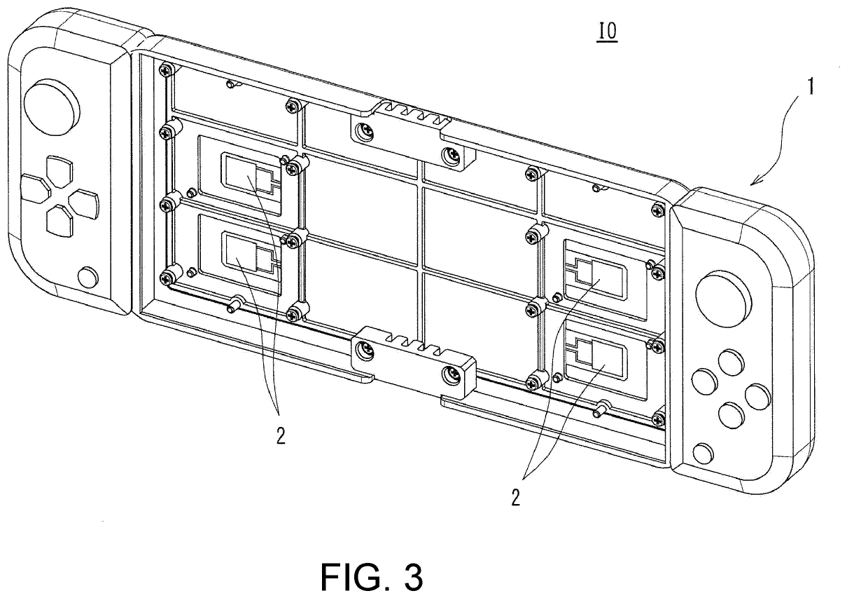

FIG. 3 is a schematic perspective view showing an example of the inside of the input-output device IO disclosed in this application. In FIG. 3, the display part 10 arranged on the front surface of the housing 1 of the input-output device IO is removed to be capable of visually recognizing the internal structure. To make the inside of the input-output device IO more visually recognizable, FIG. 3 only shows the housing 1 and piezoelectric devices 2 arranged inside the housing 1. As illustrated in FIG. 3, four piezoelectric devices 2 are arranged inside the housing 1, and the arrangement positions of the piezoelectric devices 2 correspond to the positions of the contact parts 13 on the back surface of the housing 1. With this arrangement, the piezoelectric device 2 detects an input resulting from the user's contact via the contact part 13 arranged at the housing 1, and vibration caused by the piezoelectric device 2 is transmitted as an output to the user.

<Structure of Piezoelectric Device 2>

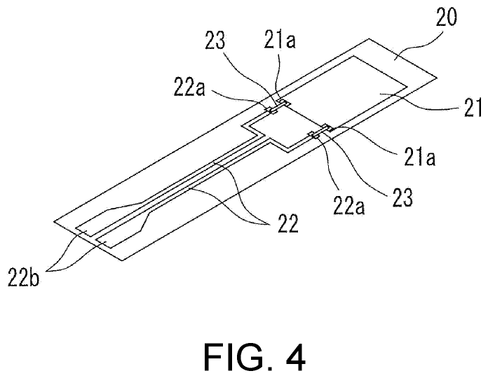

FIG. 4 is a schematic external view showing an example of the piezoelectric device 2 included in the input-output device IO disclosed in this application. The piezoelectric device 2 includes a substrate 20, a piezoelectric element 21 arranged on the substrate 20, and a printed wiring 22 formed on the substrate 20.

The substrate 20 is a flexible printed substrate (FPC substrate) formed in a substantially rectangular thin film shape and having flexibility. The substrate 20 is formed by laminating, onto a base film, a protective film protecting the piezoelectric element 21 and the printed wiring 22 on the base film.

The piezoelectric element 21 arranged on the substrate 20 is formed in a substantially rectangular thin film shape. The piezoelectric element 21 is formed using a piezo element having piezoelectricity such as lead zirconate titanate (PZT). The piezoelectric element 21 deforms upon application of a voltage, and generates a voltage in response to a pressing. Thus, by applying a periodic voltage such as in a sine wave, the piezoelectric element 21 vibrates, and with a pressing based on contact of the human body such as the user's finger, the piezoelectric element 21 generates a voltage. A pair of element electrode parts 21a serving as an input-output part of voltage are formed at the piezoelectric element 21.

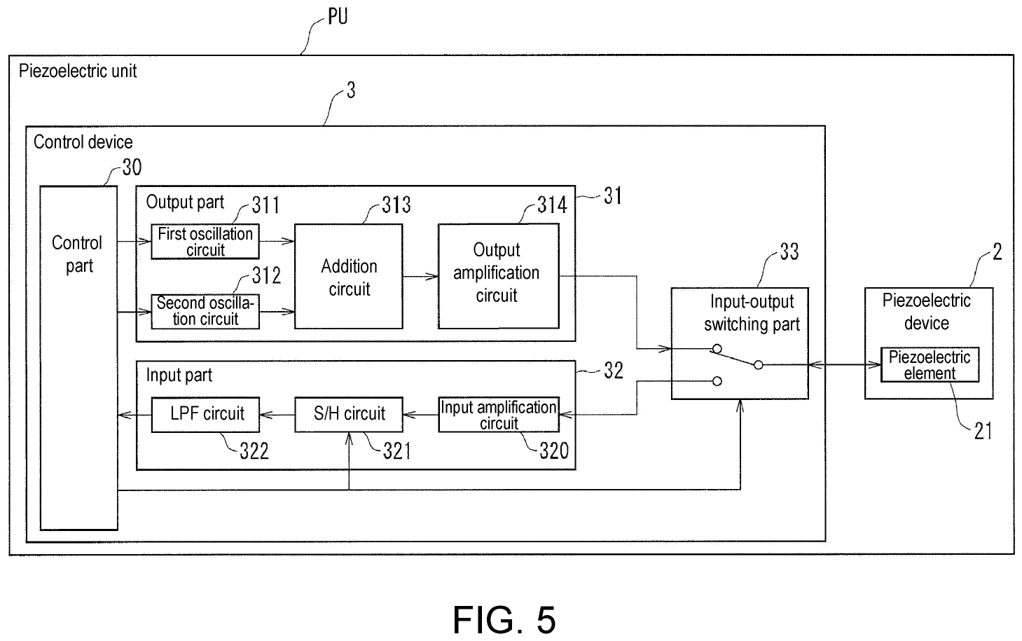

A pair of printed wirings 22 are connected to the piezoelectric element 21. One end of the printed wiring 22 serves as a wiring electrode part 22a connected to the element electrode parts 21a of the piezoelectric element 21, and the other end of the printed wiring 22 serves as a terminal part 22b. The wiring electrode part 22a and the piezoelectric element 21 are electrically connected by a conductive paste 23 using a conductive adhesive such as silver paste. The terminal part 22b is electrically connected to a control device 3 (see FIG. 5 and other figures).

<First Functional Configuration Example of Piezoelectric Unit PU>

The piezoelectric device 2 and a control device 3 that controls the piezoelectric element 21 included in the piezoelectric device 2 are accommodated in the housing 1 included in the input-output device 10. A piezoelectric unit PU that controls the piezoelectric element 21 is composed of the piezoelectric device 2 and the control device 3. The piezoelectric unit PU may be designed in various configurations depending on the control method. Hereinafter, a first functional configuration example will be described as an example of the functional configuration. FIG. 5 is a circuit block diagram schematically showing an example of the functional configuration of the control device 3 included in the piezoelectric unit PU disclosed in this application. The control device 3 included in the piezoelectric unit PU includes various components such as a control part 30, an output part 31, an input part 32, and an input-output switching part 33.

The control part 30 is a processor that controls the entire control device 3. The output part 31 is a circuit that performs output of an output signal vibrating the piezoelectric element 21 included in the piezoelectric device 2 based on the control of the control part 30. The input part 32 is a circuit that receives input of an input signal based on the voltage generated by the piezoelectric element 21 and passes the input signal to the control part 30. The input-output switching part 33 is a circuit that switches between the output performed by the output part 31 and the input performed by the input part 32 based on the control of the control part 30.

Each of the circuits will be further described. The control part 30 controls the output part 31 to control vibration of the piezoelectric element 21, and receives, from the input part 32, a signal based on the voltage inputted from the piezoelectric element 21. The control part 30 which has received an input performs various control and signal processing based on the inputted signal. Further, the control part 30 outputs a switching signal to the input-output switching part 33 and the input part 32. The switching signal is a signal that switches between an output mode of applying a voltage to the piezoelectric device 2 to drive the piezoelectric element 21, and an input mode of receiving an input of a voltage outputted by the piezoelectric element 21 due to the user's contact. The control part 30 performs time-sharing control that switches between the output mode and the input mode at timings based on a predetermined time ratio that is set in advance.

The output part 31 includes various circuits such as a first oscillation circuit 311, a second oscillation circuit 312, an addition circuit 313, and an output amplification circuit 314.

The first oscillation circuit 311 and the second oscillation circuit 312 are circuits that oscillate a signal based on the control of the control part 30. The first oscillation circuit 311 oscillates a first signal of a first frequency and outputs the first signal to the addition circuit 313. The second oscillation circuit 312 oscillates a second signal of a second frequency and outputs the second signal to the addition circuit 313. The first signal is outputted as a periodic signal having a waveform of a sine wave of 200 Hz, for example. The second signal is outputted as a periodic signal having a waveform of a sine wave of a frequency differing from the first signal by 1 to 50 Hz, for example, having a waveform of a sine wave of 203 Hz.

The addition circuit 313 receives inputs of the first signal outputted from the first oscillation circuit 311 and the second signal outputted from the second oscillation circuit 312, and combines the waveform of the first signal and the waveform of the second signal. The addition circuit 313 outputs a signal of the combined waveform to the output amplification circuit 314. The output amplification circuit 314 amplifies the signal of the combined waveform inputted from the addition circuit 313 and outputs a signal of the amplified waveform as an output signal to the input-output switching part 33.

The input-output switching part 33 is a switch circuit that switches input and output between the piezoelectric device 2 and the control device 3 based on the switching signal outputted from the control part 30. In the case of the output mode in which the input-output switching part 33 is located on the output side, an output signal of a combined waveform that is combined by the addition circuit 313 and amplified by the output amplification circuit 314 is outputted, and a voltage based on the output signal is applied to the piezoelectric element 21 included in the piezoelectric device 2. In other words, the output signal is outputted as a driving signal driving the piezoelectric device 2. In the case of the input mode in which the input-output switching part 33 is located on the input side, an input of an input signal based on a voltage generated by the piezoelectric element 21 is received from the piezoelectric device 2 and is outputted to the input part 32.

The input part 32 includes various circuits such as an input amplification circuit 320, a sample and hold (S/H) circuit 321, and a low pass filter (LPF) circuit 322.

The input amplification circuit 320 is a circuit that amplifies the waveform of an input signal inputted from the piezoelectric device 2 and outputs the input signal to the S/H circuit 321. The S/H circuit 321 is a circuit that samples and holds the waveform of the amplified input signal at a predetermined cycle. The LPF circuit 322 is a circuit that outputs the value sampled and held by the S/H circuit 321 as a smooth waveform to the control part 30. The S/H circuit 321 performs processing such as sampling and holding only in periods of the input mode based on the switching signal outputted from the control part 30.

With the piezoelectric unit PU configured as described above, the control device 3 performs time-sharing control of switching such that the output mode and the input mode of the piezoelectric device 2 alternate with each other.

Next, an example of the control performed by the piezoelectric unit PU will be described. The first signal oscillated by the first oscillation circuit 311 and the second signal oscillated by the second oscillation circuit 312 provided in the output part 31 are periodic signals of waveforms having periodicity, such as sine waves, square waves, and sawtooth waves. A configuration using sine waves as the periodic signals will be illustrated and described as the first functional configuration example. The frequencies of the first signal and the second signal are controlled between 50 and 500 Hz, and are preferably around 200 Hz. Further, the frequencies of the first signal and the second signal are different, and a difference in frequency is controlled between 1 and 50 Hz, and is preferably controlled in the range of 2 to 3 Hz. For example, as described above, the control part 30 controls the first oscillation circuit 311 and the second oscillation circuit 312 such that the frequency of the first signal is 200 Hz and the frequency of the second signal is 203 Hz.

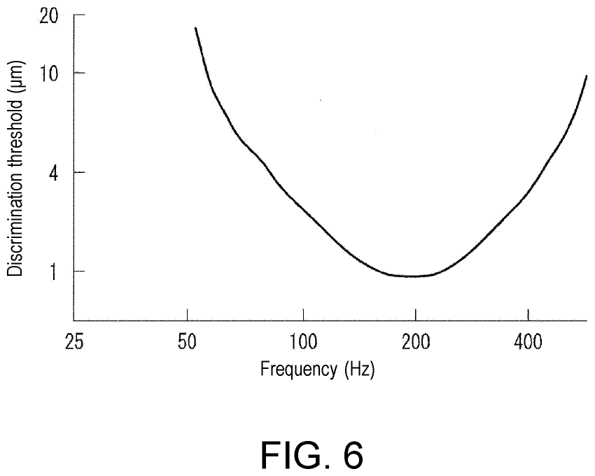

FIG. 6 is a graph showing an example of the influence of frequency on human skin sensation. In FIG. 6, the horizontal axis represents a frequency, the vertical axis represents a discrimination threshold at which Pacinian corpuscles perceive a vibration amplitude, the relationship therebetween is shown. Pacinian corpuscles are one of mechanical receptors found in the human skin. As shown in the graph of FIG. 6, Pacinian corpuscles are most sensitive to vibration of a frequency around 200 Hz and are capable of perceiving even an amplitude of about 1 μm. Thus, the frequencies related to the first signal oscillated by the first oscillation circuit 311 and the second signal oscillated by the second oscillation circuit 312 are preferably controlled between 50 and 500 Hz, and are more preferably controlled around 200 Hz.

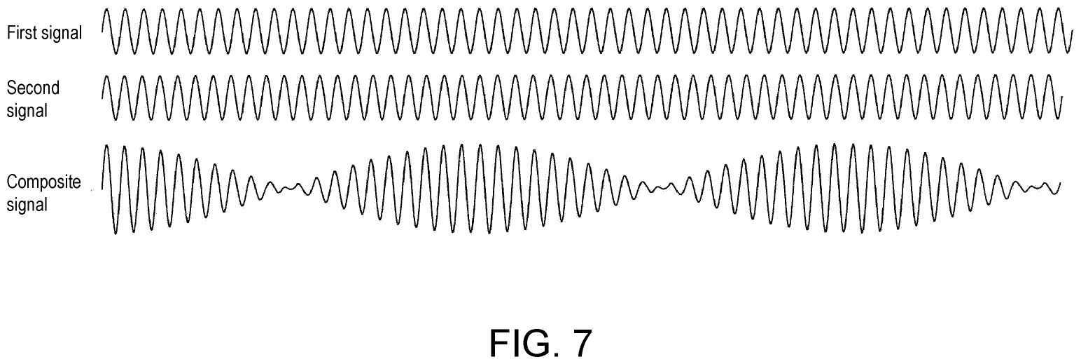

FIG. 7 is a time chart showing an example of signal waveforms related to the output part 31 of the control device 3 included in the piezoelectric unit PU disclosed in this application. FIG. 7 is a time chart showing, from top to bottom, a waveform of the first signal oscillated by the first oscillation circuit 311, a waveform of the second signal oscillated by the second oscillation circuit 312, and a waveform of a composite signal combined by the addition circuit 313. Each graph shows a change over time of a signal value, with the horizontal axis representing time and the vertical axis representing a voltage as the signal value. The first signal shown in the upper part of the figure has a waveform with a frequency of 200 Hz, and the second signal shown in the middle part of the figure has a waveform with a frequency of 203 Hz. The waveform of the composite signal shown in the lower part of the figure is a periodic signal in which a beat of 3 Hz, which is the difference in frequency, occurs. The skin sensation of the human body is more sensitive to vibration with changes than vibration with a constant frequency. The inventors of this application have found through experiments that, in the case where the beat is 1 to 50 Hz, vibration can be perceived more sensitively than at a constant frequency, and particularly, in the case where the beat is 2 to 3 Hz, vibration can be perceived most sensitively. Thus, signals of different frequencies are preferably oscillated by the first oscillation circuit 311 and the second oscillation circuit 312, and the difference in frequency between the signals is preferably 1 to 50 Hz, and more preferably 2 to 3 Hz.

An example of the time-sharing control in the piezoelectric unit PU will be described. In the first functional configuration example, the control part 30 outputs a switching signal to synchronize the periods of the input mode with periods in which an amplitude of the output signal becomes smaller than a predetermined value due to the beat. That is, in the piezoelectric unit PU disclosed in this application, with the switching signal outputted from the control part 30 to the input-output switching part 33 according to the amplitude, the input mode applies in periods in which the amplitude of the output signal becomes smaller than the predetermined value, and the output mode applies in periods in which the amplitude of the output signal becomes equal to or greater than the predetermined value. In this manner, the piezoelectric unit PU performs time-sharing control of switching such that the input performed by the input part 32 in periods of the input mode and the output performed by the output part 31 in periods of the output mode alternate with each other based on the periodic signals. Thus, in the piezoelectric unit PU disclosed in this application, it is possible to use one piezoelectric element 21 as an element for input and output, detect an input resulting from contact of the user's finger, and perform an output that transmits vibration to the user's finger. In the piezoelectric unit PU disclosed in this application, to synchronize the control of switching performed by the control part 30 with the output signal generated due to the beat, design may be performed appropriately, such as outputting an output signal from the output part 31 to the control part 30.

<Second Functional Configuration Example of Piezoelectric Unit PU>

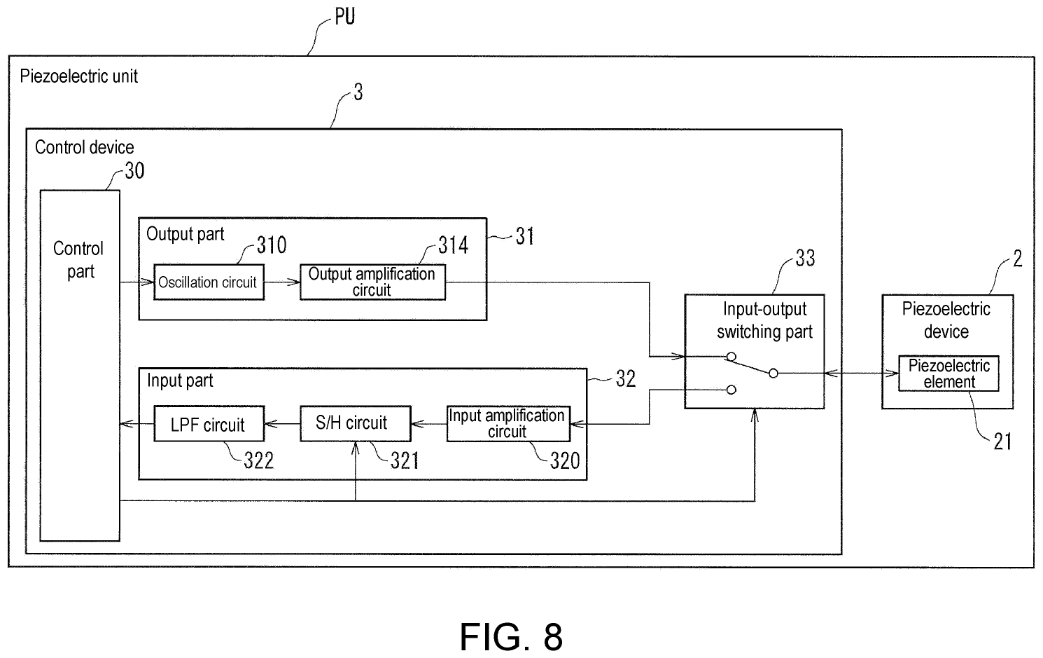

A second functional configuration example of the piezoelectric unit PU has a configuration in which a periodic signal is oscillated by one oscillation circuit 310 in the first functional configuration example. FIG. 8 is a circuit block diagram schematically showing an example of the functional configuration of the control device 3 included in the piezoelectric unit PU disclosed in this application. The control device 3 included in the piezoelectric unit PU related to the second functional configuration example includes various configurations such as a control part 30, an output part 31, an input part 32, and an input-output switching part 33. The output part 31 includes an oscillation circuit 310 and an output amplification circuit 314. The configurations of the control part 30, the input part 32, and the input-output switching part 33 are substantially similar to those in the first functional configuration example, so reference is made to the description of the first functional configuration example and detailed descriptions thereof will be omitted.

The oscillation circuit 310 included in the output part 31 oscillates a periodic signal of a waveform having periodicity, such as a sine wave, a square wave, and a sawtooth wave, and outputs the periodic signal to the output amplification circuit 314. A configuration using a square wave as the periodic signal will be illustrated and described as the second functional configuration example. The output amplification circuit 314 amplifies the signal inputted from the oscillation circuit 310 and outputs a signal of the amplified waveform as an output signal to the input-output switching part 33.

An example of time-sharing control performed by the piezoelectric unit PU related to the second functional configuration example will be described. The time-sharing control method in the piezoelectric unit PU related to the second functional configuration example is designed with various specifications according to the response performance of the piezoelectric element 21. A first control method will be described in the case where the response performance vibrating the piezoelectric element 21 is relatively high, for example, in the case where the response time when vibrating the piezoelectric element 21 is equal to or less than 2 ms.

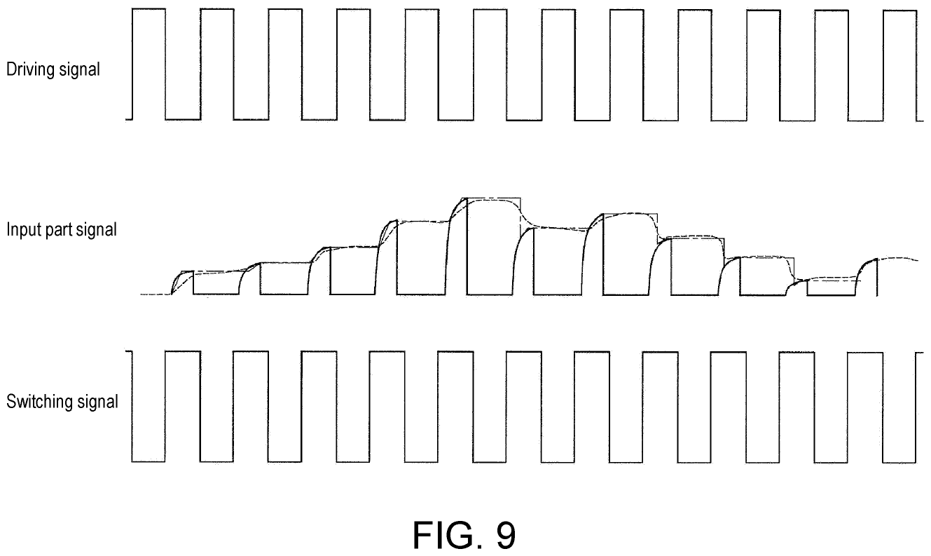

FIG. 9 is a time chart showing an example of general forms of signal waveforms related to the first control method of the control device 3 included in the piezoelectric unit PU disclosed in this application. FIG. 9 includes graphs showing, from top to bottom, a waveform of a driving signal outputted from the output part 31 via the input-output switching part 33, waveforms of various signals processed by the input part 32, and a waveform of a switching signal outputted from the control part 30. Each graph shows a change over time in a signal value, with the horizontal axis representing time and the vertical axis representing the signal value. The switching signal shown in the lower part of the figure indicates periods of the output mode at a low level and periods of the input mode at a high level.

The driving signal shown in the upper part of the figure is a signal outputted from the input-output switching part 33 in periods of the output mode at the low level of the switching signal shown in the lower part of the figure, among the output signal inputted from the output part 31 to the input-output switching part 33. The output signal and the switching signal are controlled to have the same cycle with reversed periods of the high level and the low level, so the output signal is outputted from the input-output switching part 33 as the driving signal in periods of the high level (i.e., the switching signal is at the low level).

The waveforms of various signals processed by the input part 32 shown in the middle part of the figure are presented by superposing a waveform of the input signal shown in a solid line, a waveform processed by the S/H circuit 321 shown in a dot-dashed line, and a waveform processed by the LPF circuit 322 shown in a dashed line. The input signal shown in a solid line is a signal inputted from the input-output switching part 33 in periods of the input mode at the high level of the switching signal shown in the lower part of the figure, and indicates a voltage based on human contact detected by the piezoelectric element 21 via the contact part 13 in periods of the input mode. The signal processed by the S/H circuit 321 shown in a dot-dashed line has a waveform that holds the signal value of a sampled duration until a next sampling. The signal processed by the LPF circuit 322 shown in a dashed line has a waveform in a shape obtained by smoothing the waveform of the signal processed by the S/H circuit 321.

As illustrated in FIG. 9, the first control method is a control method that switches the output mode and the input mode at a same time interval based on the cycle of the square wave used as the output signal and the switching signal. That is, the piezoelectric unit PU switches between the output performed by the output part 31 and the input performed by the input part 32 based on the periodic signal such as a square wave oscillated by the oscillation circuit 310. In the case where the response time of the piezoelectric element 21 is equal to or less than 2 ms, the piezoelectric device 2 sets the switching cycle to 5 ms, for example, and switches between the output mode and the input mode every 2.5 ms. In this manner, the piezoelectric unit PU disclosed in this application can use one piezoelectric element 21 as an element for input and output, detect an input resulting from contact of the user's finger, and perform an output of transmitting vibration to the user's finger.

Next, a second control method will be described in the case where the response performance vibrating the piezoelectric element 21 is relatively low, for example, in the case where the response time when vibrating the piezoelectric element 21 is equal to or more than 2 ms.

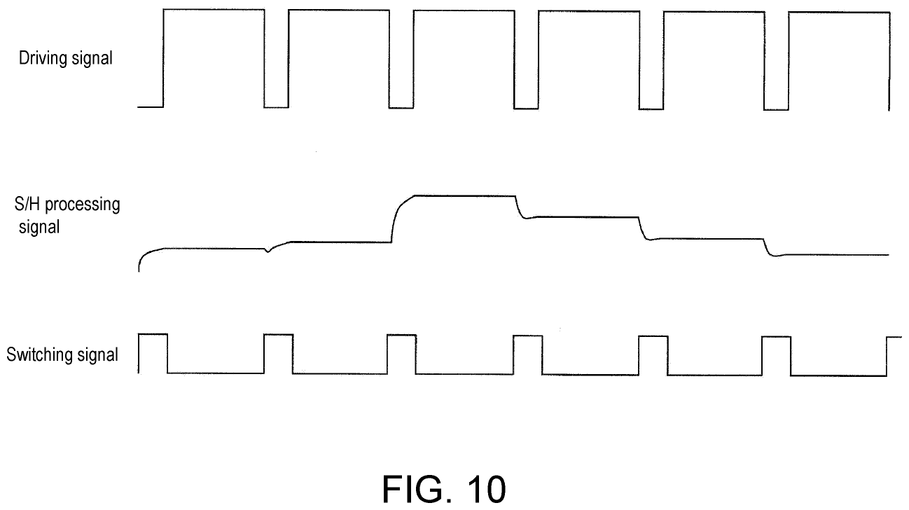

FIG. 10 includes graphs showing an example of general shapes of signal waveforms related to the second control method of the control device 3 included in the piezoelectric unit PU disclosed in this application. FIG. 10 includes graphs showing, from top to bottom, a waveform of a driving signal outputted from the output part 31 via the input-output switching part 33, a waveform of a signal processed by the input part 32, and a waveform of a switching signal outputted from the control part 30. Each graph shows a change over time in a signal value, with the horizontal axis representing time and the vertical axis representing the signal value. The switching signal shown in the lower part of the figure indicates periods of the output mode at a low level and periods of the input mode at a high level.

The driving signal shown in the upper part of the figure is a signal outputted from the input-output switching part 33 in periods of the output mode at the low level of the switching signal shown in the lower part of the figure, among the output signal inputted from the output part 31 to the input-output switching part 33. The original output signal is, for example, as illustrated in the upper part of FIG. 9, a rectangular signal in which the high level and the low level switch at a same duration, so switching is performed multiple times also within the period of the high level illustrated in FIG. 10. However, in the upper part of FIG. 10, for convenience of illustration, the signal is simplified and shown in a constant signal value as a general shape.

The waveform of the signal processed by the input part 32 shown in the middle part of the figure shows a waveform processed by the S/H circuit 321 as a representative.

As illustrated in FIG. 10, the second control method is a control method that switches the output mode and the input mode at different time intervals. By configuring a longer period of the output mode, the second control method can sufficiently exert its function even in the case of using a piezoelectric element 21 with a low response performance.

As described above, the piezoelectric unit PU disclosed in this application uses one piezoelectric element 21 as an element for output and an element for input and controls the piezoelectric element 21 by time-sharing. Thus, compared to a configuration that separately includes an element for output and an element for input, the piezoelectric unit PU disclosed in this application can simplify configurations such as wiring and control required for the elements. Accordingly, the piezoelectric unit PU disclosed in this application achieves various effects such as cost reduction, miniaturization, ease of design, and decrease in failure rate.

Further, since the piezoelectric unit PU disclosed in this application switches between the output mode and the input mode according to the switching signal, excellent effects are achieved, such as being capable of separating the circuits on the output part 31 side and the circuits on the input part 32 side and suppressing occurrence of crosstalk.

Furthermore, the piezoelectric unit PU disclosed in this application is capable of limiting the time of vibrating the piezoelectric element 21 according to the driving signal to only the periods of the output mode. Thus, the piezoelectric unit PU disclosed in this application achieves excellent effects, such as being capable of reduce a stress count of the piezoelectric element 21 and expecting a longer life.

The disclosure is not limited to the embodiments described above, and may be implemented in various other forms. Thus, the above embodiments are simply illustrative in all respects and should not be interpreted as restrictive. The technical scope of the disclosure is described according to the claims and is not bound by the text of the description. Furthermore, all modifications and changes that belong to the equivalent scope of the claims are within the scope of the disclosure.

For example, in the above embodiments, as the first functional configuration example illustrated in FIG. 5, a configuration has been illustrated to perform time-sharing control using the first oscillation circuit 311, the second oscillation circuit 312, and the addition circuit 313 and utilizing a beat due to amplitude modulation. The time-sharing control utilizing a beat generated by the piezoelectric unit PU disclosed in this application may be implemented in various forms. For example, the piezoelectric unit PU disclosed in this application may also control a duty ratio by phase control and perform time-sharing control utilizing a beat. In the case of utilizing a beat in phase control, as shown in the second functional configuration example illustrated in FIG. 8, it is possible to realize the piezoelectric unit PU using one oscillation circuit 310.

Further, for example, in the second functional configuration example, the piezoelectric unit PU disclosed in this application may expand into various configurations that switch between the input and the output based on a periodic signal, such as performing control as the output mode at the time when the output signal switches from the low level to the high level and the time when the output signal switches from the high level to the low level.

Furthermore, for example, although the above embodiments have shown a configuration of performing time-sharing control with digital circuits, the piezoelectric unit PU disclosed in this application is not limited thereto and may expand into various configurations, such as performing control with digital circuits other than the illustrated circuits or with analog circuits. For example, the analog circuit may be a flip-flop circuit that uses an oscillation circuit 310 oscillating a signal having periodicity such as a triangular wave, and compares the value of the signal oscillated by the oscillation circuit 310 with a threshold signal inputted to a comparator to switch between the output mode and the input mode.

Further, for example, the above embodiments have described a configuration of applying the input-output device IO disclosed in this application to a game device, but the input-output device IO disclosed in this application is not limited thereto and may be applied to various devices that convey a status or information to a user by vibration, such as smartphones and tablet computers.

What is claimed is:

1. A piezoelectric unit comprising:
a piezoelectric element;
an output part that performs an output vibrating the piezoelectric element;
an input part that receives an input of a voltage generated by the piezoelectric element; and
a control part that performs switching such that the output performed by the output part and the input performed by the input part alternate with each other.

2. The piezoelectric unit according to claim 1, further comprising an oscillation circuit that oscillates a periodic signal, wherein
the output performed by the output part and the input performed by the input part are switched based on the periodic signal oscillated by the oscillation circuit.

3. The piezoelectric unit according to claim 1, wherein the output part comprises:
a first oscillation circuit that oscillates a first signal of a first frequency;
a second oscillation circuit that oscillates a second signal of a second frequency different from the first frequency; and
an addition circuit that combines a waveform of the first signal oscillated by the first oscillation circuit and a waveform of the second signal oscillated by the second oscillation circuit, and
the output vibrating the piezoelectric element is an output that vibrates the piezoelectric element based on a waveform combined by the addition circuit.

4. The piezoelectric unit according to claim 3, wherein a difference between the first frequency and the second frequency is 1 to 50 Hz.

5. The piezoelectric unit according to claim 3, wherein the first frequency and the second frequency are 50 to 500 Hz.

6. The piezoelectric unit according to claim 4, wherein the first frequency and the second frequency are 50 to 500 Hz.

7. An input-output device comprising:
the piezoelectric unit according to claim 1;
a housing that accommodates the piezoelectric unit; and
a contact part arranged on an outer surface of the housing, wherein
the contact part outputs vibration caused by the piezoelectric element and transmits an input resulting from contact from outside to the piezoelectric element.

8. An input-output device comprising:
the piezoelectric unit according to claim 2;
a housing that accommodates the piezoelectric unit; and
a contact part arranged on an outer surface of the housing, wherein
the contact part outputs vibration caused by the piezoelectric element and transmits an input resulting from contact from outside to the piezoelectric element.

9. An input-output device comprising:
the piezoelectric unit according to claim 3;
a housing that accommodates the piezoelectric unit; and
a contact part arranged on an outer surface of the housing, wherein
the contact part outputs vibration caused by the piezoelectric element and transmits an input resulting from contact from outside to the piezoelectric element.
